(19) United States
(12) Patent Application Publication
(10) Pub. No.: US 2006/0256533 A1
(43) Pub. Date: Nov. 16, 2006

(54) THERMALLY DISSIPATING AND POWER DISPERSING ADHESIVELY BONDED METAL-PRINTED CIRCUIT BOARD STRUCTURE

(75) Inventor: Brian Scigiel, Southgate, MI (US)

Correspondence Address: BROOKS KUSHMAN P.C. / LEAR CORPORATION, 1000 TOWN CENTER, TWENTY-SECOND FLOOR, SOUTHFIELD, MI, 48075-1238, US

(73) Assignee: LEAR CORPORATION, Southfield, MI (US)

(21) Appl. No.: 10/908,483

(22) Filed: May 13, 2005

(51) Int. Cl. H05K 7/20; H05K 1/00

(52) U.S. Cl. 361/720; 174/252

(57) ABSTRACT

An electronic device includes one or more active or passive electronic components, one or more metal coupons, and a printed circuit board. The one or more active electronic components are mounted on a first side of a printed circuit board while the one or more metal coupons are mounted on a second side of the printed circuit board. The electronic device further includes an adhesive that bonds at least a portion of the metal coupon to the second side of the printed circuit board. A method of making the electronic devices includes the steps of forming a metal coupon into a predetermined shape followed by adhering the metal coupon to a printed circuit board.

### BACKGROUND OF THE INVENTION

1. Field of the Invention

The present invention is related to printed circuit boards with heat removing components.

2. Background Art

The automobile industry is consistently driven by the need to simultaneously provide additional features while decreasing vehicle weight and costs. Moreover, the inclusion of these additional features is also limited by the amount of available space for housing such options and associated components.

It is known that the components within electronic devices generate heat that needs to be sufficiently dissipated for efficient operation. A number of cooling mechanisms are used to reduce the temperature of electrical components in such devices. Examples of passive cooling mechanisms include components such as heat sinks. In some prior art designs, vias are used to carry heat away from components. These prior art via constructions are usually open channels which lead from an electronic component mounted on a circuit board to the other side of the circuit board. Active cooling methods using fans or cooling lines are expensive and complicated. Moreover, these active methods require significant amounts of space which is at a premium in a motor vehicle.

Junction boxes are an example of an electronic device that is found in motor vehicles. These devices typically include one or more printed circuit boards having one or more electronic components mounted thereon. These electronic components include switches and drivers used to control virtually any electronic feature found in an automobile. Examples include, switches and drivers for controlling headlights, windshield wipers, turn signals, power window motors, and combinations thereof. Junction boxes are often mounted in a vehicle's passenger compartment which as explained above has limited space. The combination of increasing electrical options in vehicles and limited space challenges the current approaches used to dissipate heat in automobile junction boxes.

Accordingly, there exists a need in the prior art for improved electronic devices with either reduced sizes or with increased number of electronic components therein.

### SUMMARY OF THE INVENTION

The present invention overcomes one or more problems of the prior art by providing in one embodiment an electronic device with improved heat transfer characteristics. The electronic device of this embodiment includes one or more active or passive electronic components, one or more metal coupons, and a printed circuit board. The one or more active electronic components are mounted on a first side of a printed circuit board while the one or more metal coupons are mounted on a second side of the printed circuit board. This embodiment further includes an adhesive that bonds at least a portion of the metal coupon to the second side of the printed circuit board. Advantageously, the metal coupon is adapted to simultaneously transfer heat from an electrical signal across the printed circuit board. The electronic device of the present invention is particularly useful for incorporation into a junction box, and in particularly, for incorporation into the type of junction box used in an automobile.

In another embodiment of the invention, a method of forming the electronic device set forth above is provided. The electronic device is formed from a printed circuit board having one or more vias and one or more electronic components mounted thereto. The method of this embodiment comprises forming a metal coupon into a predetermined shape followed by adhering the metal coupon to a printed circuit board. Advantageously, the electronic device includes one or more vias in communication with the one or more electronic components such that the metal coupon simultaneously transfers heat from an electrical signal across the printed circuit board.

### BRIEF DESCRIPTION OF THE DRAWINGS

FIG. 1 is a top perspective view of an embodiment of the electronic devices of the present invention in which electrical components are mounted on one side of a printed circuit board and metal coupons on the opposite side;

FIG. 2 is a bottom perspective view of an embodiment of the electronic devices of the present invention in which electrical components are mounted on one side of a printed circuit board and metal coupons on the opposite side; and

FIG. 3 is a cross-sectional view of an embodiment of the electronic devices of the present invention in which electrical components are mounted on one side of a printed circuit board and metal coupons on the opposite side.

### DETAILED DESCRIPTION OF THE PREFERRED EMBODIMENT(S)

Reference will now be made in detail to presently preferred compositions or embodiments and methods of the invention, which constitute the best modes of practicing the invention presently known to the inventors.

The term “via” as used herein means a small hole or passage in a printed circuit board that connects two sides of the circuit board or two layers of the circuit board.

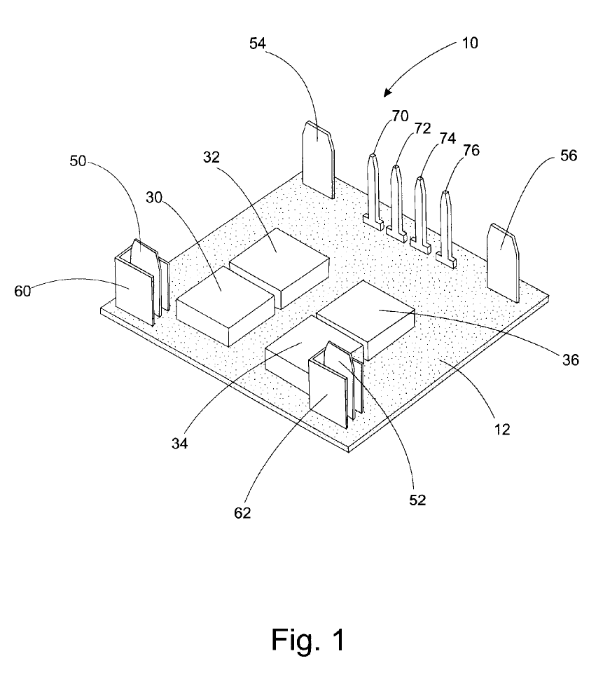

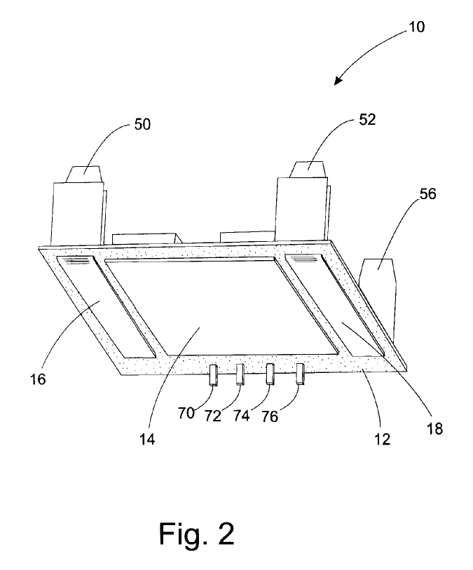

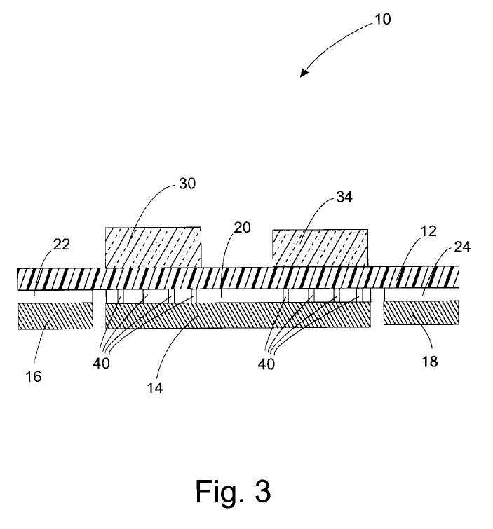

With reference to FIGS. 1-3, schematics of the electronic device of the present invention in provided. Electronic device 10 includes printed circuit board 12 and metal coupons 14, 16, 18. Metal coupons 14, 16, 18 are adhered to printed circuit board 12 by adhesives 20, 22, 24. In one variation of the invention, adhesives 20, 22, 24 are adhesive layers. Examples of suitable adhesive layers include, but are not limited to, 3M's Thermally Conductive Adhesive Transfer Tapes #8805, #8810, #8815, and #8820. Circuit board 12 typically includes one or more active or passive electronic components 30, 32, 34, 36. Examples of suitable passive electronic components include, but is not limited to, passive electronic components selected from the group consisting of resistors, capacitors, inductors, transformers, and combinations thereof. Additional examples for the one or more active or passive electronic components include switches, drivers, and combinations thereof. Also, this latter example usually includes active components although passive switches and drivers are also embraced by the present invention. In many applications, such switches and drivers are used to control a vehicle (i.e., automobile) component. Examples of such vehicle components include, but are not limited to headlights, windshield wipers, turn signals, power window motors, and combinations thereof. The temperature of components 30, 32, 34, 36 is maintained at sufficiently low temperatures by heat transport to metal coupons 14, 16, 18. In a variation of the invention, heat transport to metal coupons 14, 16, 18 is assisted by one or more vias 40 which transfer heat from components 30, 32, 34, 36 to metal coupons 14, 16, 18.

In another variation of the present embodiment, metal coupons 16, 18 are also adapted to transfer an electrical signal across the printed circuit board. An example of such an electrical signal transfer is a DC or AC power signal that provides electrical power to at least one of electronic component 30, 32, 34, 36. In this variation, metal coupons 16, 18 includes one or more metal protrusions 50, 52, 54, 56 that pass through printed circuit board 12 extending past the first side of the printed circuit board. In a refinement of this variation, one or more metal protrusions 50, 52, 54, 56 are in the shape of a blade that may function as a male connector. Optionally, one or more of metal protrusions 50, 52, 54, 56 are adjacent to shrouds 60, 62 which are used to protect the protrusion and/or to assist in the attachment of cables to the protrusions. Typically, the electronic device of the invention includes additional contact blades 70, 72, 74, 76 for attachment to other cables contacting electronic device 10. This additional cabling may be used for any purpose such as carrying control or power signals.

In another embodiment of the invention, a method of forming the electronic device set forth above is provided. With reference to FIGS. 1-3, electronic device 10 is formed from printed circuit board 12 which has one or more vias 40 and one or more electronic components mounted 30, 32, 34, 36 thereto. The method of this embodiment comprises forming metal coupons 14, 16, 18 into a predetermined shape followed by adhering the metal coupon to printed circuit board 12. When metal coupons 14, 16, 18 may be formed by any metal forming process. Stamping has been found to be particularly useful. In a variation of this embodiment as set forth above, metal coupons 16, 18 includes one or more metal protrusions 50, 52, 54, 56 that pass through printed circuit board 12 extending past the first side of the printed circuit board. In a refinement of this variation, one or more metal protrusions 50, 52, 54, 56 are in the shape of a blade that may function as a male connector. Protrusions 50, 52, 54, 56 are formed by bending the ends of metal coupons 16, 18 into the desired blade-like shape. Advantageously, electronic device 10 includes one or more vias 40 in communication with the one or more electronic components such that metal coupons 14, 16, 18 simultaneously transfers heat from an electrical signal across printed circuit board 12.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. An electronic device comprising:
one or more active or passive electronic components;
a printed circuit board having a first side and second side wherein the one or more active or passive electronic components are mounted on the first side;
a metal coupon; and
an adhesive bonding at least a portion of the metal coupon to the second side of the printed circuit board, wherein the metal coupon is adapted to simultaneously transfer heat from an electrical signal across the printed circuit board.

2. The electronic device of claim 1 wherein at least a portion of the heat from the one or more active or passive electronic components is transferred to the metal coupon by one or more vias.

3. The electronic device of claim 1 wherein the electrical signal is a DC or AC power signal that provides electrical power to at least one electronic component.

4. The electronic device of claim 1 wherein the metal coupon includes one or more metal protrusions that pass through the printed circuit board extending past the first side of the printed circuit board.

5. The electronic device of claim 4 wherein the one or more protrusions are a male connector blade.

6. The electronic device of claim 1 wherein the one or more active or passive electronic components comprise a passive electronic component selected from the group consisting of resistors, capacitors, inductors, transformers, and combinations thereof.

7. The electronic device of claim 1 wherein the one or more active or passive electronic components comprise a component selected from the group consisting of switches, drivers, and combinations thereof.

8. The electronic device of claim 7 wherein the one or more active or passive electronic components are used for controlling a vehicle component selected from the group consisting of headlights, windshield wipers, turn signals, power window motors, and combinations thereof.

9. A junction box comprising the electronic device of claim 1.

10. An electronic device comprising:
one or more electronic components;
a printed circuit board having a first side and second side wherein the one or more active or passive electronic components are mounted on the first side;
one or more vias;
a metal coupon in communication with at least one of the one or more electronic components by the one or more vias; and
an adhesive bonding at least a portion of the metal coupon to the second side of the printed circuit board, wherein the metal coupon is adapted to transfer heat from the printed circuit board.

11. The electronic device of claim 10 wherein the metal coupon transfers an electrical signal across the printed circuit board.

12. The electronic device of claim 10 wherein the electrical signal is a DC or AC power signal that provides electrical power at least one electronic component.

13. The electronic device of claim 10 wherein the metal coupon is a stamped metal coupon.

14. The electronic device of claim 10 wherein the metal coupon includes one or more metal protrusions that pass through the printed circuit board extending past the first side of the printed circuit board.

15. The electronic device of claim 14 wherein the one or more protrusions are a male connector blade.

16. The electronic device of claim 10 wherein the one or more active or passive electronic components comprise a passive electronic component selected from the group consisting of resistors, capacitors, inductors, transformers, and combinations thereof.

17. The electronic device of claim 16 wherein the one or more active or passive electronic components comprise a component selected from the group consisting of switches, drivers, and combinations thereof.

18. The electronic device of claim 17 wherein the one or more active or passive electronic components are used for controlling a vehicle component selected from the group consisting of headlights, windshield wipers, turn signals, power window motors, and combinations thereof.

19. A method of forming an electronic device from a printed circuit board having one or more vias and one or more electronic components mounted thereto, the method comprising:
forming a metal coupon into a predetermined shape;
adhering the metal coupon to a printed circuit board, wherein the one or more vias are in communication with one or more electronic components such that the metal coupon simultaneously transfers heat from an electrical signal across the printed circuit board.

20. The method of claim 19 wherein the metal coupon includes one or more metal protrusions that pass through the printed circuit board extending past the first side of the printed circuit board.
